(19) United States
(12) Patent Application Publication
(10) Pub. No.: US 2026/0113939 A1
(43) Pub. Date: Apr. 23, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Na Yeong YANG, Icheon-si Gyeonggi-do (KR); Jung Shik JANG, Icheon-si Gyeonggi-do (KR)

(73) Assignee: SK hynix Inc., Icheon-si Gyeonggi-do (KR)

(21) Appl. No.: 19/091,482

(22) Filed: Mar. 26, 2025

(30) Foreign Application Priority Data
Oct. 18, 2024 (KR) 10-2024-0142985

(51) Int. Cl. H10B 43/27; H10B 43/10

(52) U.S. Cl. CPC H10B 43/27; H10B 43/10

(57) ABSTRACT

A method of manufacturing a memory device includes forming a first stack including alternately stacked first interlayer insulating layers and first sacrificial layers, the first sacrificial layers having a first etch rate; forming a second stack over the first stack, the second stack including alternately stacked second interlayer insulating layers and second sacrificial layers, the second sacrificial layers having a second etch rate lower than the first etch rate; forming first sacrificial pillars penetrating the second stack; forming preliminary openings by removing the first sacrificial pillars; forming first openings penetrating a first number of the first sacrificial layers, respectively, by etching a portion of the first stack through the preliminary openings; forming second openings penetrating the first number of the second sacrificial layers, respectively, by etching a portion of the second stack spaced apart from the preliminary openings; and forming contacts in the first openings and the second openings.

### CROSS-REFERENCE TO RELATED APPLICATION

The present application claims priority under 35 U.S.C. § 119(a) to Korean patent application number 10-2024-0142985, filed on Oct. 18, 2024, in the Korean Intellectual Property Office, the entire disclosure of which application is incorporated herein by reference.

### BACKGROUND

### 1. Technical Field

The present disclosure relates to a memory device and a manufacturing method of the memory device, and more particularly, to a memory device including a memory block having a three-dimensional structure and a method of manufacturing the memory device having the three-dimensional structure.

### 2. Related Art

A memory device may include a non-volatile memory device that retains stored data even in the absence of supplied power. A non-volatile memory device may be classified as a two-dimensionally structured memory device or a three-dimensionally structured memory device depending on the arrangement of memory cells within the device. Memory cells of a non-volatile memory device having a two-dimensional structure may be arranged in a single layer on a substrate. Memory cells of a non-volatile memory device having a three-dimensional structure may be stacked in a vertical direction to the substrate. Because the integration density of a non-volatile memory device having a three-dimensional structure is greater than that of a non-volatile memory device having a two-dimensional structure, electronic devices including three-dimensionally structured non-volatile memory devices have been increasing.

### SUMMARY

According to an embodiment of the present disclosure, a method of manufacturing a memory device may include: forming a lower stack including first interlayer insulating layers and first sacrificial layers alternately stacked with each other in a first direction; forming an upper stack over the lower stack in the first direction, wherein the upper stack includes second interlayer insulating layers and second sacrificial layers alternately stacked with each other in the first direction, the second sacrificial layers having a lower etch rate than the first sacrificial layers; forming a preliminary opening penetrating through the upper stack and exposing an upper surface of the lower stack; and forming a first opening extending in the first direction from one of the first sacrificial layers and a second opening extending in the first direction from one of the second sacrificial layers by simultaneously etching a portion of the lower stack exposed through the preliminary opening and a portion of the upper stack spaced apart from the preliminary opening.

According to an embodiment of the present disclosure, a method of manufacturing a memory device may include: forming a first stack including first interlayer insulating layers and first sacrificial layers alternately stacked with each other, the first sacrificial layers having a first etch rate; forming a second stack over the first stack, wherein the second stack includes second interlayer insulating layers and second sacrificial layers alternately stacked with each other, the second sacrificial layers having a second etch rate lower than the first etch rate; forming first sacrificial pillars penetrating through the second stack; forming preliminary openings by removing the first sacrificial pillars; forming first openings penetrating a first number of the first sacrificial layers, respectively, by etching a portion of the first stack through the preliminary openings; forming second openings penetrating the first number of the second sacrificial layers, respectively, by etching a portion of the second stack spaced apart from the preliminary openings; and forming contacts in the first openings and the second openings.

According to an embodiment of the present disclosure, a memory device may include: a first cell stack including first conductive layers and first interlayer insulating layers alternately stacked with each other; a second cell stack including second conductive layers and second interlayer insulating layers alternately stacked with each other over the first cell stack; cell plugs penetrating through each of the first cell stack and the second cell stack; a first contact extending in a vertical direction from one of the first conductive layers; a second contact extending in the vertical direction from one of the second conductive layers; a first dummy stack in a horizontal direction of the first cell stack and including the first interlayer insulating layers and the first sacrificial layers stacked alternately with each other; and a second dummy stack in a horizontal direction of the second cell stack and including the second interlayer insulating layers and the second sacrificial layers stacked alternately with each other. Further, an etch rate of the second sacrificial layers may be lower than an etch rate of the first sacrificial layers.

### BRIEF DESCRIPTION OF THE DRAWINGS

FIG. 1 is a diagram illustrating a memory device according to an embodiment of the present disclosure;

FIG. 2 is an isometric view illustrating a memory device according to an embodiment of the present disclosure;

FIGS. 3A to 3C are diagrams illustrating a memory device including contacts formed according to an embodiment of the present disclosure;

FIGS. 4A to 4H are diagrams for describing a method of manufacturing contacts in two stacks including different sacrificial layers with different etch rates;

FIGS. 5A to 5H are diagrams for describing a method of manufacturing contacts in four stacks including different sacrificial layers with different etch rates;

FIGS. 6A and 6B are diagrams for describing a method of manufacturing contacts in stacks according to another embodiment of the present disclosure;

FIGS. 7A to 7D are diagrams for describing a method of manufacturing contacts in stacks according to another embodiment of the present disclosure;

FIG. 8 is a diagram illustrating a memory card system to which a memory device according to an embodiment of the present disclosure is applied; and

FIG. 9 is a diagram illustrating a solid state drive (SSD) system to which a memory device according to an embodiment of the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, embodiments of the present disclosure will be described in detail with reference to the accompanying drawings for those skilled in the art to be able to implement the technical spirit of the present disclosure. According to an embodiment, for example, a memory device may be manufactured with improved contact quality.

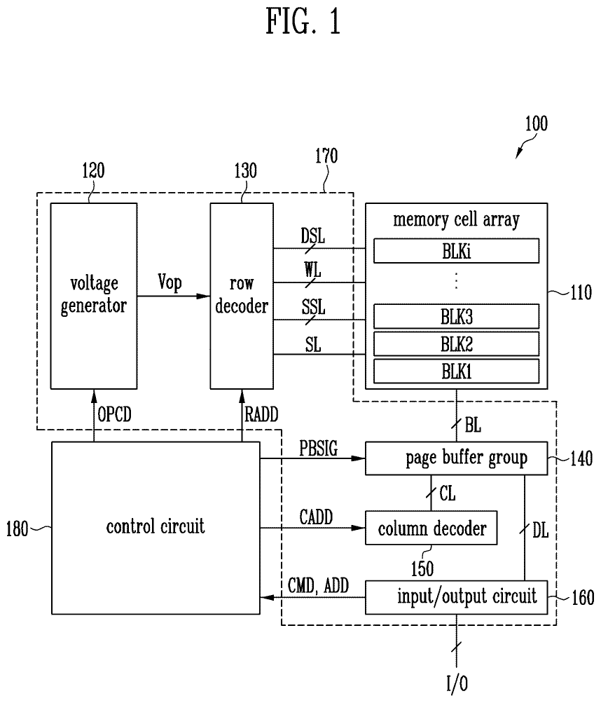

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells which store data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

The first to ith memory blocks BLK1 to BLKi may have a three-dimensional structure. The three-dimensionally structured memory blocks may include memory cells which are stacked in a direction perpendicular to a substrate.

The memory cells may include 1-bit data or two or more bits of data according to a program method. For example, a method of storing one bit in a single memory cell is referred to as a single-level cell method, and a method of storing two bits of data is referred to as a multi-level cell method. A method of storing three bits of data in a single memory cell is referred to as a triple-level cell method. A method of storing four bits of data is referred to as a quad-level cell method. Further, five or more bits of data may be stored in a single memory cell.

The peripheral circuit 170 may include a program operation for storing data in the memory cell array 110, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop which are applied to perform a program operation, a read operation, or an erase operation in response to an operating code OPCD. For example, the voltage generator 120 may be configured to generate program voltages, turn-on voltages, turn-off voltages, negative voltages, precharge voltages, verify voltages, read voltages, pass voltages, or erase voltages in response to the operating code OPCD. The operating voltages Vop generated by the voltage generator 120 may be applied to the drain select lines DSL, the word lines WL, the source select lines SSL, and the source line SL of a selected memory block through the row decoder 130.

Program voltages may be applied to a selected word line among the word lines WL during a program operation and used to increase threshold voltages of memory cells coupled to the selected word line. Turn-on voltages may be applied to the drain select lines DSL or the source select lines SSL and used to turn on drain select transistors or source select transistors. Turn-off voltages may be applied to the drain select lines DSL or the source select lines SSL and used to turn on the drain select transistors or the source select transistors. For example, a turn-off voltage may be set to 0 V. Precharge voltages may be greater than 0 V and be applied to bit lines during a read operation. Verify voltages may be used during a verify operation for determining whether threshold voltages of selected memory cells are increased to a target level. The verify voltages may be set to various levels depending on the target level and applied to the selected word line.

Read voltages may be applied to the selected word line during a read operation of selected memory cells. For example, the read voltages may be set to various levels according to a program method of the selected memory cells. Pass voltages may be applied to unselected word lines, among the word lines WL, during a read or erase operation and may be used to turn on memory cells coupled to the unselected word lines. Erase voltages may be used during an erase operation for erasing memory cells included in the selected memory block, and may be applied to the source line SL.

The row decoder 130 may be configured to apply the operating voltages Vop to the drain select lines DSL, the word lines WL, the source select lines SSL, and the source line SL which are coupled to the selected memory block depending on a row address RADD. For example, the row decoder 130 may be coupled to the voltage generator 120 through global lines and first to ith memory blocks BLK1 to BLKi through the drain select lines DSL, the word lines WL, the source select lines SSL, and the source line SL.

The page buffer group 140 may include page buffers (not shown) which are coupled to the first to ith memory blocks BLK1 to BLKi, respectively. Each of the page buffers may be coupled to the first to ith memory blocks BLK1 to BLKi through the bit lines BL. During a read operation, each of the page buffers may sense currents or voltages in bit lines which vary depending on threshold voltages of selected memory cells in response to page buffer control signals PBSIG and may temporarily store sensed data.

The column decoder 150 may be configured to transfer data between the page buffer group 140 and the input/output circuit 160 in response to a column address CADD. For example, the column decoder 150 may be coupled to the page buffer group 140 through column lines CL and transfer enable signals through the column lines CL. The page buffers (not shown) included in the page buffer group 140 may receive or output data through data lines DL in response to the enable signals.

The input/output circuit 160 may receive or output a command CMD, an address ADD and data through input/output lines I/O. For example, the input/output circuit 160 may transfer the command CMD and the address ADD, which are received from an external controller through the input/output lines I/O, to the control circuit 180, and may transfer the data, which is received from the external controller through the input/output lines I/O, to the page buffer group 140. Alternatively, the input/output circuit 160 may output the data, which is received from the page buffer group 140, to the external controller through the input/output lines I/O.

The control circuit 180 may output at least one of the operating code OPCD, the row address RADD, the page buffer control signals PBSIG, and the column address CADD in response to the command CMD and the address ADD. For example, when the command CMD which is input to the control circuit 180 corresponds to a program operation, the control circuit 180 may control the peripheral circuit 170 to perform the program operation on the selected memory block by the address ADD. When the control circuit 180 corresponds to a read operation, the control circuit 180 may control the peripheral circuit 170 to perform the read operation on the selected memory block by the address and output the read data. When the command CMD which is input to the control circuit 180 corresponds to an erase operation, the control circuit 180 may control the peripheral circuit 170 to perform the erase operation on the selected memory block.

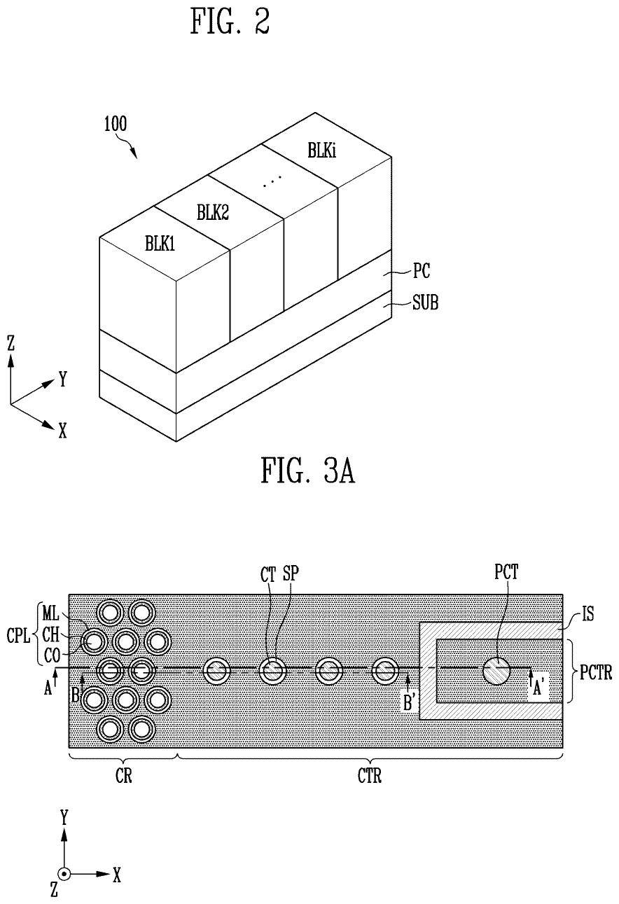

FIG. 2 is an isometric view illustrating the memory device 100 according to an embodiment of the present disclosure.

Referring to FIG. 2, the memory device 100 may include a peripheral circuit structure PC and the first to ith memory blocks BLK1 to BLKi arranged over a substrate SUB. The first to ith memory blocks BLK1 to BLKi may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by using a selective epitaxial growth technique.

The peripheral circuit structure PC may include a row decoder 130, a column decoder 150, a page buffer group 140, and a control circuit 180 which constitute a circuit for controlling operations of the first to ith memory blocks BLK1 to BLKi. For example, the peripheral circuit structure PC may include one or more of an NMOS transistor, a PMOS transistor, a resistor, and a capacitor which are electrically coupled to the first to ith memory blocks BLK1 to BLKi. The peripheral circuit structure PC may be arranged between the substrate SUB and the first to ith memory blocks BLK1 to BLKi.

Each of the first to ith memory blocks BLK1 to BLKi may include a source structure, bit lines, cell strings electrically coupled between the source structure and the bit lines, word lines electrically coupled to the cell strings, and select lines electrically coupled to the cell strings. Each of the cell strings may include memory cells and select transistors which are coupled in series by a cell plug. Each of the select lines may serve as a gate electrode of a corresponding one of the select transistors. Each of the word lines may serve as a gate electrode of a corresponding one of the memory cells.

As the length of the first to ith memory blocks BLK1 to BLKi in the Z direction increases, a double stack method or a multi-stack method of stacking two or more stacks may be used. For example, each of the first to ith memory blocks BLK1 to BLKi may include a first stack and a second stack over the first stack, and each of the cell plugs included in the first to ith memory blocks BLK1 to BLKi may include a first portion in the first stack and a second portion in the second stack.

In another embodiment, the substrate SUB, the peripheral circuit structure PC, and the first to ith memory blocks BLK1 to BLKi may be stacked in a reverse order to the order shown in FIG. 2. For example, the peripheral circuit structure PC may be arranged over the first to ith memory blocks BLK1 to BLKi.

In another embodiment, contrary to FIG. 2, the peripheral circuit structure PC may be arranged over some areas of the substrate SUB which do not overlap the first to ith memory blocks BLK1 to BLKi. For example, the peripheral circuit structure PC and the first to ith memory blocks BLK1 to BLKi may be respectively arranged in areas of the substrate SUB which do not overlap each other.

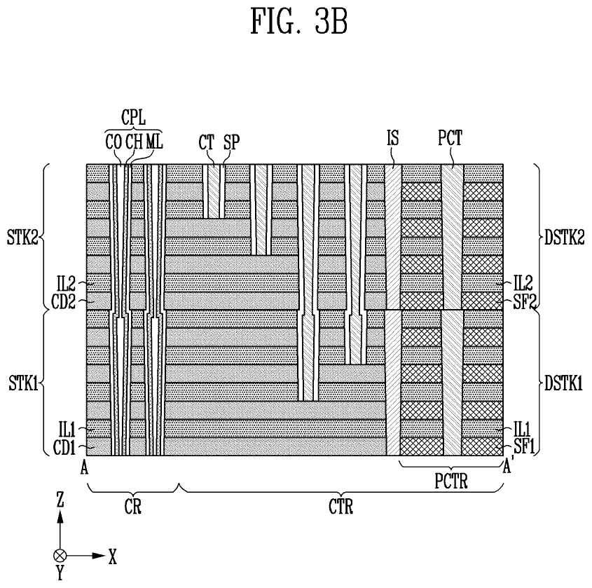

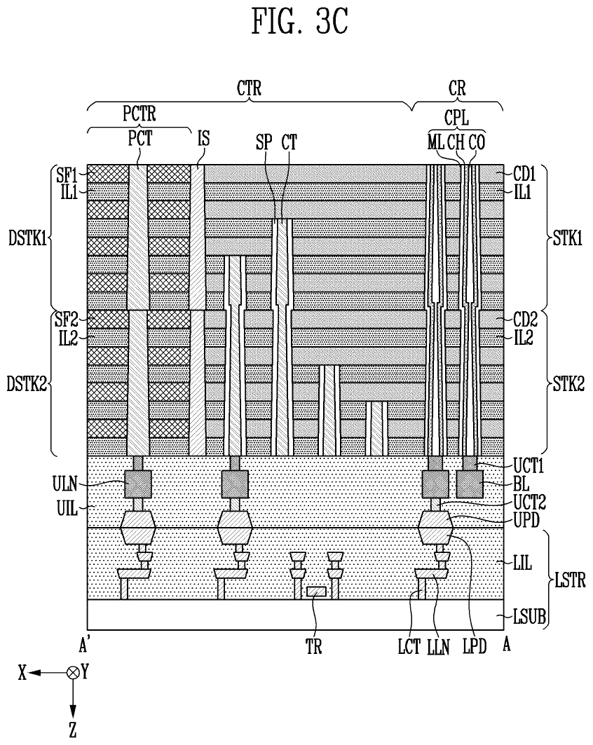

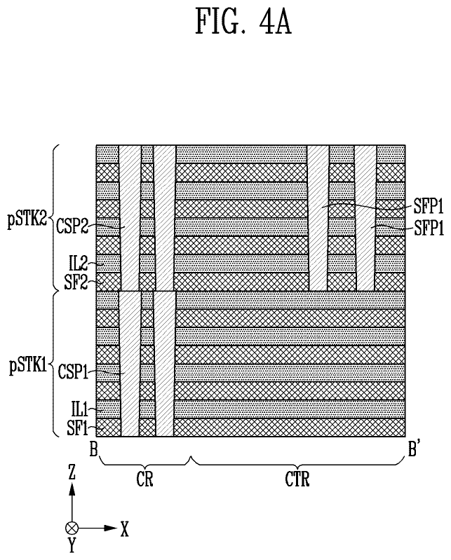

FIGS. 3A to 3C are diagrams illustrating a memory device including contacts formed according to an embodiment of the present disclosure. FIG. 3A is a plan view of a layout of a memory device according to an embodiment of the present disclosure. FIG. 3B is a cross-sectional view showing the cross section A-A′ of FIG. 3A. FIG. 3C is a cross-sectional view showing the cross section A′-A of FIG. 3A.

Referring to FIG. 3A, the memory device 100 (e.g., any one of the first to ith memory blocks BLK1 to BLKi of FIG. 2) may include a cell region CR and a contact region CTR. The contact region CTR may be in an X direction of the cell region CR. The contact region CTR may extend from the cell region CR in the X direction. Contrary to FIG. 3A, the contact region CTR may extend from the cell region CR in a Y direction, or may extend in the X direction and the Y direction. In addition, the cell region CR and the contact region CTR may be arranged in various manners.

Cell plugs CPL may be in the cell region CR. The cell plugs CPL may be arranged in the X and Y directions. The cell plugs CPL may be spaced apart from each other in the X direction and the Y direction. Each of the cell plugs CPL may extend in the Z direction. Each of the cell plugs CPL may be electrically coupled to a bit line (e.g., the bit line BL of FIG. 1) and a source line (e.g., the source line SL of FIG. 1) through a wiring structure.

Each of the cell plugs CPL may include a memory layer ML, a channel layer CH, and a core pillar CO. In an embodiment, the memory layer ML may have a cylindrical shape. The memory layer ML may include a circular cross section in the X-Y plane. The memory layer ML may surround the channel layer CH. Though not shown in FIG. 3A, the memory layer ML may include a blocking layer, a charge trap layer, and a tunneling layer.

In another embodiment, contrary to FIG. 3A, the memory layer ML include an elliptical-shaped or a clover-shaped cross section in the X-Y plane. The memory layer ML may be formed on at least a portion of an inner surface of a hole which has the elliptical- or clover-shaped cross section. For example, the memory layer ML may cover the entire inner surface of the hole. In another example, the memory layer ML may cover only a portion of the inner surface of the hole. That is, two or more cell strings which are separated from each other may be formed in one hole. However, for convenience of explanation, it is assumed that the cell plugs CPL has a circular cross section in the X-Y plane.

A blocking layer and a tunneling layer which are included in the memory layer ML may include an oxide layer (e.g., a silicon oxide layer) or an oxynitride layer (e.g., a silicon oxynitride layer), or a combination thereof. A charge trap layer which is included in the memory layer ML may include a nitride layer or a variable resistance material.

The channel layer CH may be formed on an inner wall of the memory layer ML. The core pillar CO may fill the inside of the channel layer CH. The core pillar CO may have a cylindrical shape which is surrounded by the channel layer CH. The channel layer CH may include an undoped silicon layer or a doped silicon layer. The core pillar CO may include an insulating layer (e.g., an oxide layer) or a conductive layer.

Contacts CT may be in the contact region CTR. A plurality of contacts may be arranged in the contact region CTR. FIG. 3A shows only some of the contacts CT. The contacts CT may be spaced apart from each other in the X direction. The contacts CT may be arranged in the X direction. In addition, the contacts CT may be variously arranged in the contact region CTR. Each of the contacts CT may extend in a Z direction. The contacts CT may include a conductive material. The contacts CT may be referred to as word line contacts or contact plugs.

Spacers SP may surround the contacts CT, respectively. The spacers SP may be in contact with sides of the contacts CT. The contacts CT may fill the insides of the spacers SP, respectively. The spacers SP may include an insulating layer. For example, the spacers SP may include an oxide layer.

The memory device 100 may further include a peripheral contact region PCTR. The peripheral contact region PCTR may be in the contact region CTR. For example, the peripheral contact region PCTR may correspond to a portion of the contact region CTR. The peripheral contact region PCTR may be surrounded by an isolation structure IS. The isolation structure IS may separate the peripheral contact region PCTR from the remaining portion of the contact region CTR.

Peripheral circuit contacts PCT may be arranged in the peripheral contact region PCTR. The peripheral circuit contacts PCT may penetrate the peripheral contact region PCTR. The peripheral circuit contacts PCT may extend in the Z direction. The peripheral circuit contacts PCT may be electrically coupled to the peripheral circuit structure PC of FIG. 2.

Referring to FIG. 3B, the memory device 100 may include a first stack STK1 and a second stack STK2. The second stack STK2 may be arranged on the first stack STK1. The second stack STK2 may be in the Z direction of the first stack STK1. An upper surface of the first stack STK1 may be in contact with a lower surface of the second stack STK2. The first and second stacks STK1 and STK2 may be referred to as first and second cell stacks, respectively. The first and second stacks STK1 and STK2 may extend from the cell region CR to the contact region CTR. The first and second stacks STK1 and STK2 may be in the cell region CR and the contact region CTR.

The first stack STK1 may include first conductive layers CD1 and first interlayer insulating layers IL1. The first conductive layers CD1 and the first interlayer insulating layers IL1 may be stacked alternately with each other in the Z direction. The second stack STK2 may include second conductive layers CD2 and second interlayer insulating layers IL2. The second conductive layers CD2 and the second interlayer insulating layers IL2 may be stacked alternately with each other in the Z direction. The first and second conductive layers CD1 and CD2 may include at least one of tungsten (W), cobalt (Co), nickel (Ni), molybdenum (Mo), silicon (Si), or polysilicon (poly-Si). The first and second conductive layers CD1 and CD2 may include the same material. The first and second conductive layers CD1 and CD2 may correspond to gate lines (e.g., the drain select line DSL, the word line WL, and the source select line SSL in FIG. 1). The first and second interlayer insulating layers IL1 and IL2 may include an oxide layer (for example, a silicon oxide layer). The first and second interlayer insulating layers IL1 and IL2 may include the same material.

The memory device 100 may include a first dummy stack DSTK1 and a second dummy stack DSTK2. The second dummy stack DSTK2 may be arranged on the first dummy stack DSTK1. The second dummy stack DSTK2 may be in the Z direction of the first dummy stack DSTK1. An upper surface of the first dummy stack DSTK1 may be in contact with a lower surface of the second dummy stack DSTK2. The first dummy stack DSTK1 may be in a horizontal direction (e.g., the X direction) of the first stack STK1. The first dummy stack DSTK1 may be at the same level as the first stack STK1. The second dummy stack DSTK2 may be in a horizontal direction (e.g., X direction) of the second stack STK2. The second dummy stack DSTK2 may be at the same level as the second stack STK2. The first and second dummy stacks DSTK1 and DSTK2 may be in the peripheral contact region PCTR. The isolation structure IS may be between the first dummy stack DSTK1 and the first stack STK1. The isolation structure IS may be between the second dummy stack DSTK2 and the second stack STK2.

The first dummy stack DSTK1 may include first sacrificial layers SF1 and first interlayer insulating layers IL1. The first interlayer insulating layers IL1 included in the first dummy stack DSTK1 may be at the same level as the first interlayer insulating layers IL1 included in the first stack STK1. The first interlayer insulating layers IL1 included in the first dummy stack DSTK1 may include the same material as the first interlayer insulating layers IL1 included in the first stack STK1. The first sacrificial layers SF1 may be at the same level as the first conductive layers CD1. The isolation structure IS may allow the first sacrificial layers SF1 to remain without being replaced by the first conductive layers CD1.

The second dummy stack DSTK2 may include second sacrificial layers SF2 and second interlayer insulating layers IL2. The second interlayer insulating layers IL2 included in a second dummy stack DSTK2 may be at the same level as the second interlayer insulating layers IL2 included in the second stack STK2. The second interlayer insulating layers IL2 included in the second dummy stack DSTK2 may include the same material as the second interlayer insulating layers IL2 included in the second stack STK2. The second sacrificial layers SF2 may be at the same level as the second conductive layers CD2. The isolation structure IS may allow the second sacrificial layers SF2 to remain without being replaced by the second conductive layers CD2.

The first sacrificial layers SF1 and the second sacrificial layers SF2 may include a material having an etch selectivity with respect to the first and second interlayer insulating layers IL1 and IL2. The first and second sacrificial layers SF1 and SF2 may include a nitride material. For example, the first and second sacrificial layers SF1 and SF2 may include silicon nitride.

In the present disclosure, the first sacrificial layers SF1 and the second sacrificial layer SF2 may have different etch rates. The first sacrificial layers SF1 may have a first etch rate, and the second sacrificial layers SF2 may have a second etch rate. The second etch rate may be lower than the first etch rate. The etch rate of the second sacrificial layers SF2 may be slower than the etch rate of the first sacrificial layers SF1. That is, etch rates of sacrificial layers may increase toward a lower portion of a stack, and etch rates of the sacrificial layers may decrease toward an upper portion of the stack.

In an embodiment, the etch rate may vary depending on the concentration of impurities contained in the first and second sacrificial layers SF1 and SF2. The concentration of impurities contained in the second sacrificial layers SF2 may be greater than the concentration of impurities contained in the first sacrificial layers SF1. The impurities may include carbon. The impurities may be included in the first and second sacrificial layers SF1 and SF2 through a doping process or an implant process.

In another embodiment, the contents of the materials included in the first and second sacrificial layers SF1 and SF2 may be different from each other. The first sacrificial layers SF1 and the second sacrificial layers SF2 may include nitrogen (N) and silicon (Si), respectively. The ratio of silicon (Si) contained in the second sacrificial layers SF2 may be higher than the ratio of silicon (Si) contained in the first sacrificial layers SF1.

In another embodiment, the etch rates of the first and second sacrificial layers SF1 and SF2 may be set differently by varying various conditions such as thermal treatment time, the number of treatments, temperature, etc. which are applied to each of a lower stack (e.g., STK1 or DSTK1) and an upper stack (e.g., STK2 or DSTK2).

Referring to FIG. 3B, the cell plugs CPL may penetrate the cell region CR of the first and second stacks STK1 and STK2. Each of the cell plugs CPL may include the memory layer ML, the channel layer CH, and the core pillar CO. Memory cells and select transistors may be formed at respective intersections between the cell plugs CPL and the first and second conductive layers CD1 and CD2. The cell plugs CPL may serve as a channel region of a cell string. The width of each of the cell plugs CPL may vary at an interface between the first stack STK1 and the second stack STK2. For example, the width of the cell plug CPL in the X direction at the bottom of the second stack STK2 may be less than the width of the cell plug CPL in the x direction at the top of the first stack STK1.

The contacts CT may extend in the Z direction in the contact region CTR. The contacts CT may extend in the Z direction from any one of the first and second conductive layers CD1 and CD2. For example, a first contact that contacts one of the first conductive layer CD1 may penetrate the second stack STK2. The first contact may penetrate the second conductive layers CD2 and the second interlayer insulating layers IL2. The first contact may be surrounded by the second conductive layers CD2 and the second interlayer insulating layers IL2. The first contact may penetrate at least one of the first interlayer insulating layer IL1. Also, a second contact that contacts one of the second conductive layers CD2 may penetrate at least one of the second interlayer insulating layer IL2. A lower surface of each of the contacts CT may be in contact with an upper surface of any one of the first and second conductive layers CD1 and CD2. The contacts CT may be electrically coupled to the first and second conductive layers CD1 and CD2, respectively. Referring to FIG. 3B, the contact region CTR is formed in a stairless structure. For example, a length of each of the first conductive layers CD1 in the X direction is the same as a length of each of the second conductive layers CD2 in the X direction.

The spacers SP may surround the side of each of the contacts CT. The spacers SP may insulate the contacts CT from other conductive layers (e.g., CD1 and CD2) aside from the conductive layer each contact is coupled with.

The peripheral circuit contacts PCT may penetrate the first and second dummy stacks DSTK1 and DSTK2. Because the first and second dummy stacks DSTK1 and DSTK2 do not include conductive layers, a spacer might not be arranged on a side surface of the peripheral circuit contact PCT.

Though not shown, in one embodiment, a support pillar may be formed in the contact region CTR. The support pillar may extend in the Z direction in the contact region CTR. The support pillar may penetrate at least some of the first and second conductive layers CD1 and CD2 and at least some of first and second interlayer insulating layers IL1 and IL2. For example, the support pillar may penetrate the first and second stacks STK1 and STK2 in the contact region CTR. In another example, the support column may pass through the first stack STK1 from the bottom of the second stack STK2. The support pillar may support the first and second interlayer insulating layers IL1 and IL2 during the processes of forming the first and second conductive layers CD1 and CD2. The support column may have various shapes such as a cylindrical shape or an elliptical shape. The support pillar may include an insulating material.

In addition, in an embodiment, a dummy pillar may be further formed in the contact region CTR. The dummy pillar may extend in the Z direction in the contact region CTR. The dummy pillar may penetrate at least some of the first and second conductive layers CD1 and CD2 and at least some of first and second interlayer insulating layers IL1 and IL2. The dummy pillar may have various shapes such as a cylindrical shape or an elliptical shape. The dummy pillar may include an insulating material.

Referring to FIG. 3C, the first stack STK1, the second stack STK2, the first dummy stack DSTK1, and the second dummy stack DSTK2 may be stacked over a lower structure LSTR. For example, an upper insulating layer UIL may be disposed in a Z direction of the second stack STK2 and the second dummy stack DSTK2. First upper contacts UCT1, bit lines BL, upper lines ULN, second upper contacts UCT2, and upper bonding pads UPD may be disposed within the upper insulating layer UIL. The first upper contacts UCT1 may be in contact with the cell plugs CPL, the contacts CT, and the peripheral circuit contact PCT. The bit lines BL may be connected to the cell plugs CPL through the first upper contacts UCT1. The upper lines ULN may be connected to the contacts CT or the peripheral circuit contact PCT through the first upper contacts UCT1. The upper bonding pads UPD may be connected to the bit lines BL or the upper lines ULN through the second upper contacts UCT2. The lower structure LSTR may include a lower substrate LSUB, a lower insulating layer LIL, at least one transistor TR, lower contacts LCT, lower lines LLN, and lower bonding pads LPD. The upper bonding pads UPD may be in contact with the lower bonding pads LPD, respectively. A source layer (not shown) may be disposed on the first stack STK1.

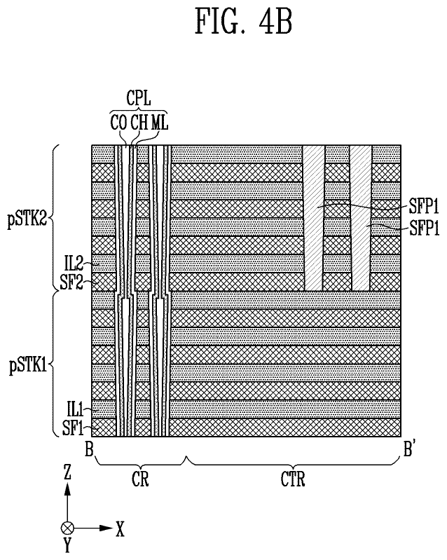

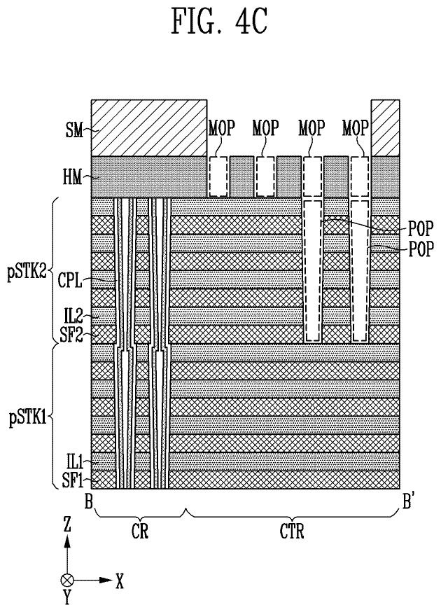

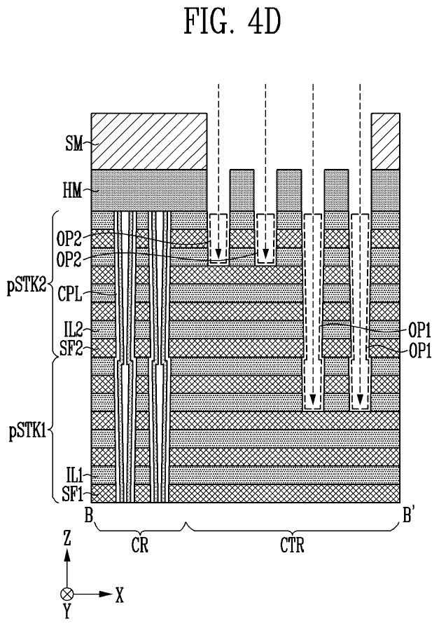

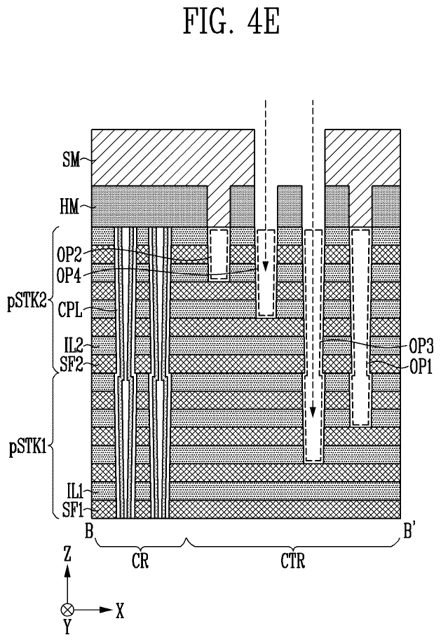

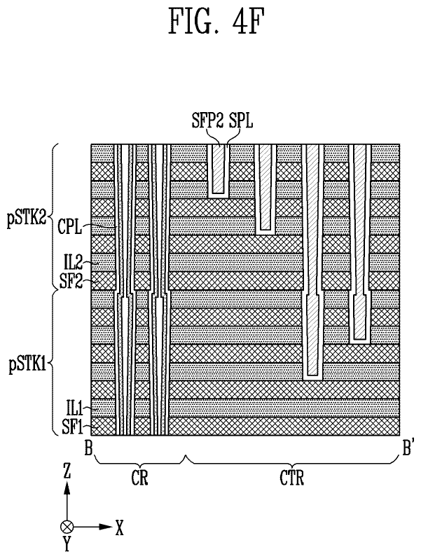

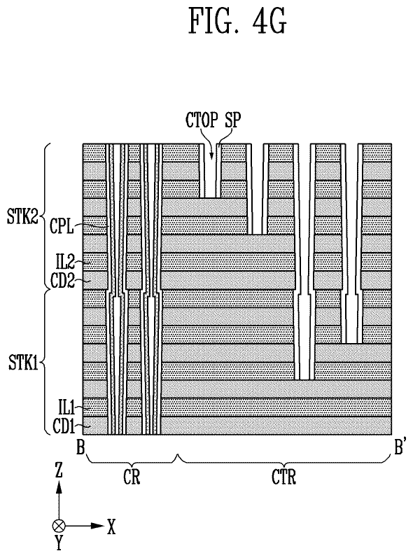

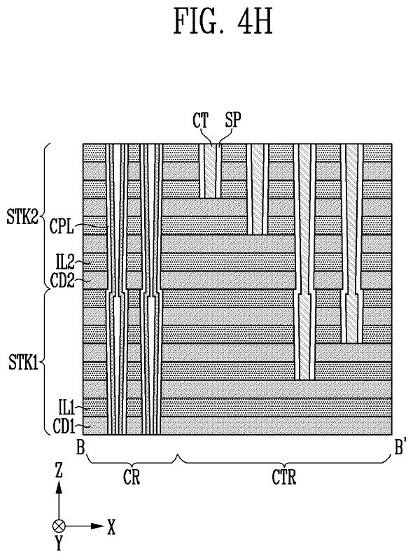

FIGS. 4A to 4H are diagrams for describing a method of manufacturing contacts in two stacks including different sacrificial layers with different etch rates. FIGS. 4A to 4H are cross-sectional views corresponding to a cross section B-B′ of FIG. 3A.

Referring to FIG. 4A, a first preliminary stack pSTK1 may be formed in which first interlayer insulating layers IL1 and first sacrificial layers SF1 are stacked alternately with each other. The first interlayer insulating layers IL1 and the first sacrificial layers SF1 may be stacked on each other in the Z direction. The first interlayer insulating layers IL1 may include an insulating material. For example, the first interlayer insulating layers IL1 may include oxide layers (for example, silicon oxide layers). The first sacrificial layers SF1 may include a material which is selectively removed in a subsequent process. The first sacrificial layers SF1 may include a material having a different etch selectivity from that of the first interlayer insulating layers IL1. For example, the first sacrificial layers SF1 may include nitride layers.

Subsequently, first cell sacrificial pillars CSP1 may be formed through the first preliminary stack pSTK1. The first cell sacrificial pillars CSP1 may be formed in the cell region CR. Each of the first cell sacrificial pillars CSP1 may extend in the Z direction. The X-Y cross section of the first cell sacrificial pillars CSP1 may have a cylindrical shape, an elliptical shape, or a pillar shape, which fills a tapered hole in the Z direction. The first cell sacrificial pillars CSP1 may include a carbon layer. For example, the first cell sacrificial pillars CSP1 may include a carbon layer, a carbon layer and polysilicon, or a carbon layer and a metal nitride (e.g., TiN).

Subsequently, a second preliminary stack pSTK2 may be formed on the first preliminary stack pSTK1. The second preliminary stack pSTK2 may include the second interlayer insulating layers IL2 and the second sacrificial layers SF2 which are stacked alternately with each other on each other. The second interlayer insulating layers IL2 and the second sacrificial layers SF2 may be stacked on each other in the Z direction. The lowermost second sacrificial layer among the second sacrificial layers SF2 may be in contact with the uppermost first interlayer insulating layer among the first interlayer insulating layers IL1.

The second interlayer insulating layers IL2 may include an insulating material. For example, the second interlayer insulating layers IL2 may include oxide layers (for example, silicon oxide layers). The second interlayer insulating layers IL2 may include the same material as the first interlayer insulating layers IL1. The second sacrificial layers SF2 may include a material which is selectively removed in a subsequent process. The second sacrificial layers SF2 may include a material having a different etch selectivity from that of the second interlayer insulating layers IL2. For example, the second sacrificial layers SF2 may include nitride layers.

The first sacrificial layers SF1 may have a first etch rate. The second sacrificial layers SF2 may have a second etch rate. The second etch rate may be lower than the first etch rate. That is, the etch rate of the second sacrificial layers SF2 may be slower than the etch rate of the first sacrificial layers SF1.

In an embodiment, the second sacrificial layers SF2 may be formed to contain more impurities than the first sacrificial layer SF1. For example, the first and second sacrificial layers SF1 and SF2 may each contain impurities such as carbon, and the second sacrificial layers SF2 may contain more impurities than the first sacrificial layer SF1. Therefore, the etch rate of the second sacrificial layers SF2 may be slower than the etch rate of the first sacrificial layers SF1.

In another embodiment, the first and second sacrificial layers SF1 and SF2 each may include silicon (Si) and nitrogen (N), and the ratio of Si contained in the second sacrificial layers SF2 may be higher than the ratio of Si included in the first sacrificial layers SF1. For example, the first sacrificial layers SF1 may include SiaNb, and the second sacrificial layer SF2 may include SixNy, where x/y may have a larger value than a/b. Therefore, the etch rate of the second sacrificial layers SF2 may be slower than that of the first sacrificial layers SF1.

In addition, various methods can be used so that the first sacrificial layers SF1 and the second sacrificial layers SF2 may have different etch rates. For example, the etch rate of the first and second sacrificial layers SF1 and SF2 may be controlled by adjusting time, number, temperature, etc. of a thermal treatment process when each of the first preliminary stack pSTK1 and the second preliminary stack pSTK2 is formed. In another example, different types of impurities may be injected into the first and second sacrificial layers SF1 and SF2 to control their relative etch rates.

Subsequently, second cell sacrificial pillars CSP2 may be formed through the second preliminary stack pSTK2. The second cell sacrificial pillars CSP2 may be formed in the cell region CR. Each of the second cell sacrificial pillars CSP2 may extend in the Z direction. The second cell sacrificial pillars CSP2 may overlap the first cell sacrificial pillars CSP1, respectively. A lower surface of each of the second cell sacrificial pillars CSP2 may be in contact with an upper surface of a corresponding first cell sacrificial pillar CSP1 beneath it. The X-Y cross section of the second cell sacrificial pillars CSP2 may have a cylindrical shape, an elliptical shape, or a pillar shape, which fills a tapered hole in the Z direction. Because the second cell sacrificial pillars CSP2 are formed on the first cell sacrificial pillars CSP1 that are already formed, irregularities may be formed on side surfaces of the first and second cell sacrificial pillars CSP1 and CSP2 at the interfaces of the first and the second preliminary stacks pSTK1 and pSTK2. For example, a width of an upper end of each of the first cell sacrificial pillars CSP1 may be greater than a width of a lower end of each of the second cell sacrificial pillars CSP2.

In addition, first sacrificial pillars SFP1 may be formed through the second preliminary stack pSTK2. The first sacrificial pillars SFP1 may be formed in the contact region CTR. For example, the first sacrificial pillars SFP1 may be formed by etching a portion of the second preliminary stack pSTK2 in the contact region CTR and filling a sacrificial material therein. Each of the first sacrificial pillars SFP1 may extend in the Z direction. The lower surfaces of the first sacrificial pillars SFP1 may be in contact with an upper surface of the first preliminary stack pSTK1. The X-Y cross section of the first sacrificial pillars SFP1 may have a cylindrical shape, an elliptical shape, or a pillar shape, which fills a tapered hole in the Z direction.

The second cell sacrificial pillars CSP2 and the first sacrificial pillars SFP1 may include a carbon layer. For example, the second cell sacrificial pillars CSP2 and the first sacrificial pillars SFP1 may include a carbon layer, a carbon layer and polysilicon, or a carbon layer and metal nitride (e.g., TiN).

Referring to FIG. 4B, the first and second cell sacrificial pillars CSP1 and CSP2 may be removed. The spaces from which the first and second cell sacrificial pillars CSP1 and CSP2 are removed may be referred to as cell openings. For example, each cell opening may correspond to a space in which one of the first cell sacrificial pillars CSP1 and one of the second cell sacrificial pillars CSP2 are removed. The cell plugs CPL may be formed in spaces (e.g., cell openings) from which the first and second cell sacrificial pillars CSP1 and CSP2 are removed. For example, side surfaces of the first and second preliminary stacks pSTK1 and pSTK2 may be exposed as the first and second cell sacrificial pillars CSP1 and CSP2 are removed. The memory layer ML, the channel layer CH, and the core pillar CO may be sequentially formed on the side surfaces of the first and second preliminary stacks pSTK1 and pSTK2 within the cell openings.

Referring to FIG. 4C, a hard mask HM and a slimming mask SM may be formed on the second preliminary stack pSTK2. The hard mask HM may be in contact with the upper surface of the second preliminary stack pSTK2. The hard mask HM may include mask openings MOP. The mask openings MOP may correspond to locations where the contacts CT of FIGS. 3A and 3B are to be formed. The mask openings MOP may expose the first sacrificial pillars SFP1 of FIG. 4B. In addition, a portion of the upper surface of the second preliminary stack pSTK2 may be exposed by the mask openings MOP. The hard mask HM may include a nitride material. The slimming mask SM may be in contact with an upper surface of the hard mask HM. The slimming mask SM may include an opening which exposes the mask openings MOP of the hard mask HM. The slimming mask SM may include a material whose volume is reduced by thermal treatment.

Subsequently, the first sacrificial pillars SFP1 may be removed to form preliminary openings POP. The first sacrificial pillars SFP1 may be etched through the mask openings MOP. The preliminary openings POP may correspond to spaces from which the first sacrificial pillars SFP1 are removed. The preliminary openings POP may penetrate through the second preliminary stack pSTK2 and expose the upper surface of the first preliminary stack pSTK1.

Referring to FIG. 4D, portions of the first and second preliminary stacks pSTK1 and pSTK2 which are exposed through the slimming mask SM and the hard mask HM may be etched. Portions of the first preliminary stack pSTK1 which are exposed through the mask openings MOP and the preliminary openings POP may be removed to form first openings OP1. Each of the first openings OP1 may include a space corresponding to the preliminary opening POP. In addition, portions of the second preliminary stack pSTK2 exposed through the mask openings MOP may be removed to form second openings OP2. The second openings OP2 may be spaced apart from the first openings OP1 in a horizontal direction.

The first openings OP1 may extend in the Z direction from any one of the first sacrificial layers SF1. The first openings OP1 may expose an upper surface of any one of the first sacrificial layers SF1. In addition, the second openings OP2 may extend in the Z direction from any one of the second sacrificial layers SF2. The second openings OP2 may expose an upper surface of any one of the second sacrificial layers SF2.

A height of an area of the first opening OP1 except for an area corresponding to the preliminary opening POP may correspond to a height of the second opening OP2. For example, the first openings OP1 may have a depth corresponding to that of the second first sacrificial layer SF1 from the top of the first sacrificial layers SF1. In addition, the second openings OP2 may have a depth corresponding to that of the second second sacrificial layer SF2 from the top of the second sacrificial layers SF2.

Processes for forming the first and second openings OP1 and OP2 may be performed to alternately remove interlayer insulating layers (e.g., IL1 and IL2) and sacrificial layers (e.g., SF1 and SF2). Processes for sequentially etching the oxide layer and the nitride layer may be performed so that the first and second openings OP1 and OP2 have a specific depth.

The processes of etching the first and second preliminary stacks pSTK1 and pSTK2 may be performed simultaneously. Second openings OP2 and lower portions of the first openings OP1 are formed by a single etching process. For example, when an etch process using an etching gas is performed, the second preliminary stack pSTK2 may be etched by the etching gas passing through the mask opening MOP to form the second openings OP2. In addition, the first preliminary stack pSTK1 may be etched by the etching gas passing through the mask opening MOP and the preliminary opening POP to form the first openings OP1. The time for the etching gas to reach the first preliminary stack pSTK1 may be longer than the time for the etching gas to reach the second preliminary stack pSTK2. Therefore, when the first and second sacrificial layers SF1 and SF2 have the same etch rate, the degree to which the first preliminary stack pSTK1 is etched may be less than the degree to which the second preliminary stack pSTK2 is etched. However, in accordance with an embodiment of the present disclosure, because the first sacrificial layers SF1 have a faster etch rate than the second sacrificial layers SF2, even when the time taken for the etching gas to reach the first preliminary stack pSTK1 is longer than the time taken to reach the second preliminary stack pSTK2, the depth by which the first preliminary stack pSTK1 is etched may be the same as the depth by which second preliminary stack pSTK2 is etched.

Referring to FIG. 4E, the slimming mask SM may be modified to further cover a portion of the hard mask HM. For example, a new slimming mask SM may be formed after the slimming mask SM of FIG. 4D is removed, or a material corresponding to the slimming mask may be further formed on the slimming mask SM of FIG. 4D to fill some of the mask openings MOP.

Some of the first openings OP1 and some of the second openings OP2 may be left exposed by the modified slimming mask SM. The remaining first openings OP1 and second openings OP2 may be covered by the slimming mask SM.

Subsequently, a portion of the first preliminary stack pSTK1 left exposed through the first opening OP1 may be etched to form a third opening OP3. For example, the first opening OP1 on the left side among the first openings OP1 may extend downward to form the third opening OP3. In addition, a portion of the second preliminary stack pSTK2 left exposed through the second opening OP2 may be etched to form a fourth opening OP4. For example, the second opening OP2 on the right side among the second openings OP2 may extend downward to form the fourth opening OP4.

The third opening OP3 may be formed to a greater depth than the first opening OP1 by a length corresponding to the thickness of a first sacrificial layer SF1 plus the thickness of a first interlayer insulating layer IL1. The third opening OP3 may extend from any one of the first sacrificial layers SF1 in the Z direction. In addition, the fourth opening OP4 may be formed to a greater depth than the second opening OP2 by a length corresponding to the thickness of a second sacrificial layer SF2 plus the thickness of a second interlayer insulating layer IL2. The fourth opening OP4 may extend from any one of the second sacrificial layers SF2 in the Z direction.

A height of an area of the third opening OP3, except for an area corresponding to the preliminary opening POP, may correspond to a height of the fourth opening OP4. For example, the third opening OP3 may have a depth corresponding to that of the third first sacrificial layer SF1 from the top of the first sacrificial layers SF1. In addition, the fourth opening OP4 may have a depth corresponding to that of the second sacrificial layer SF2 from the top of the second sacrificial layers SF2.

As described for FIG. 4D, the process of etching the first and second preliminary stacks pSTK1 and pSTK2 may be performed simultaneously. A lower portion of the third opening OP3 and a lower portion of the fourth opening OP4 are formed by a single etching process. For example, when an etch process using an etching gas is performed, the first preliminary stack pSTK1 may be etched by the etching gas passing through the first opening OP1 to form the third opening OP3. In addition, the second preliminary stack pSTK2 may be etched by the etching gas passing through the second opening OP2 to form the fourth opening OP4. The time for the etching gas to reach the first preliminary stack pSTK1 may be longer than the time for the etching gas to reach the second preliminary stack pSTK2. In accordance with an embodiment of the present disclosure, because the first sacrificial layers SF1 have a faster etch rate than the second sacrificial layers SF2, even when the time taken for the etching gas to reach the first preliminary stack pSTK1 is longer than the time taken for the etching gas to reach the second preliminary stack pSTK2, the depth by which the first preliminary stack pSTK1 is etched may be the same as the depth by which the second preliminary stack pSTK2 is etched.

In FIGS. 4D and 4E, only the method of forming the first to fourth openings OP1 to OP4 is shown for convenience of description, but the present disclosure is not limited thereto. For example, openings coupled to each of the first sacrificial layers SF1 and openings coupled to each of the second sacrificial layer SF2 may be formed.

Referring to FIG. 4F, the slimming mask SM and the hard mask HM may be removed. Subsequently, spacer layers SPL may be formed on the inner surfaces of the first to fourth openings OP1 to OP4. The spacer layers SPL may extend on side surfaces and bottom surfaces of the first to fourth openings OP1 to OP4, respectively. The spacer layers SPL may be formed on the side and upper surfaces of the first and second preliminary stacks pSTK1 and pSTK2 which are exposed through the first to fourth openings OP1 to OP4. The spacer layers SPL may be conformally formed on the inner surfaces of the first to fourth openings OP1 to OP4. The spacer layers SPL may include an insulating material. For example, the spacer layers SPL may be oxide layers.

Subsequently, second sacrificial pillars SFP2 may be formed in the first to fourth openings OP1 to OP4. The second sacrificial pillars SFP2 may fill the first to fourth openings OP1 to OP4, respectively. The second sacrificial pillars SFP2 may be surrounded by the spacer layers SPL, respectively. The second sacrificial pillars SFP2 may be separated from the first and second preliminary stacks pSTK1 and pSTK2 by the spacer layers SPL. The second sacrificial pillars SFP2 may include a carbon layer or a conductive layer (e.g., tungsten).

Referring to FIG. 4G, the first sacrificial layers SF1 may be replaced with the first conductive layers CD1, and the second sacrificial layers SF2 may be replaced with the second conductive layers CD2. For example, the first and second sacrificial layers SF1 and SF2 may be removed, and the space between the first and second interlayer insulating layers IL1 and IL2 may be filled with a conductive material. The first and second conductive layers CD1 and CD2 may be simultaneously formed. The first and second conductive layers CD1 and CD2 may include materials equivalent to each other. The first conductive layers CD1 and the first interlayer insulating layers IL1 may form the first stack STK1. The second conductive layers CD2 and the second interlayer insulating layers IL2 may form the second stack STK2.

Though not shown here, the peripheral contact region PCTR as shown in FIG. 3A may be surrounded by the isolation structure IS. Thus, for an embodiment, the first and second sacrificial layers SF1 and SF2 might not be removed within the peripheral contact region PCTR. Therefore, the first and second sacrificial layers SF1 and SF2 may remain without being replaced by the first and second conductive layers CD1 and CD2 inside the isolation structure IS.

Subsequently, the second sacrificial pillars SFP2 may be removed from the first to fourth openings OP1 to OP4. The second sacrificial pillars SFP2 may be removed to form contact openings CTOP.

The bottom of each of the spacer layers SPL may then be removed. Spacers SP may be formed by removing lower surfaces of the spacer layers SPL through the contact openings CTOP. The spacers SP may extend on inner side surfaces of the contact openings CTOP. As the lower surfaces of the spacer layers SPL are removed, the upper surfaces of the first and second conductive layers CD1 and CD2 may be exposed through the contact openings CTOP. Each of the contact openings CTOP may expose one of the first and second conductive layers CD1 and CD2.

Referring to FIG. 4H, the contacts CT may fill the contact openings CTOP, respectively. The contacts CT may be disposed in the contact openings CTOP. The contacts CT may be in contact with the first and second conductive layers CD1 and CD2, respectively. The contacts CT may be electrically coupled to the first and second conductive layers CD1 and CD2, respectively. The contacts CT may be surrounded by the spacers SP, respectively. Therefore, each of the contacts CT may be coupled to one of the conductive layer, but not to the other conductive layers.

According to an embodiment of the present disclosure, as described with reference to FIGS. 4D and 4E, by forming the first sacrificial layers SF1 with a different etch rate from the etch rate of the second sacrificial layers SF2, openings (e.g., OP1 to OP4) for contacts (CT) may be formed. Therefore, by controlling the etch rates of the first and second sacrificial layers SF1 and SF2 which are stacked alternately with each other with the first and second interlayer insulating layers IL1 and IL2, the quality of the contacts CT may be improved and the manufacturing processes of the contacts CT may be complemented.

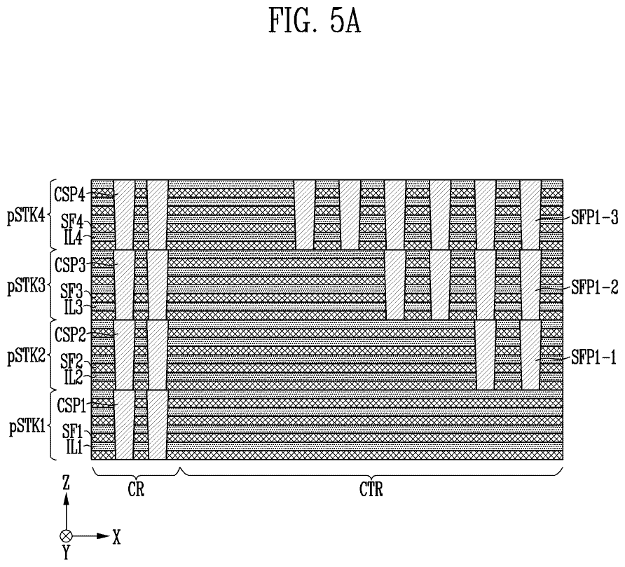

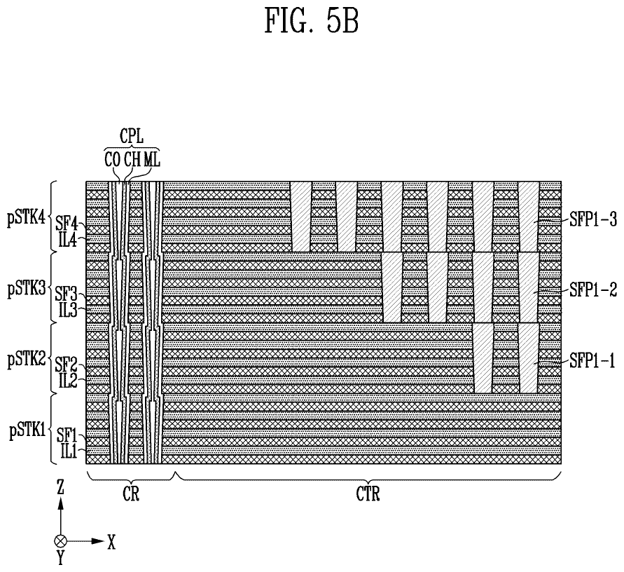

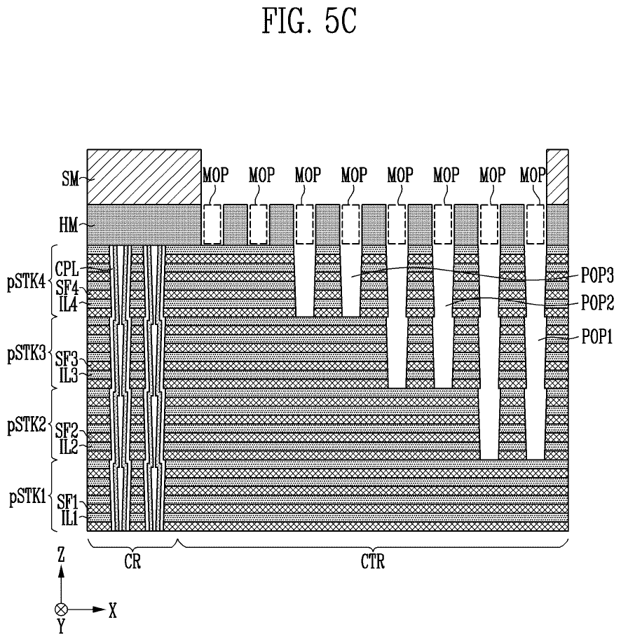

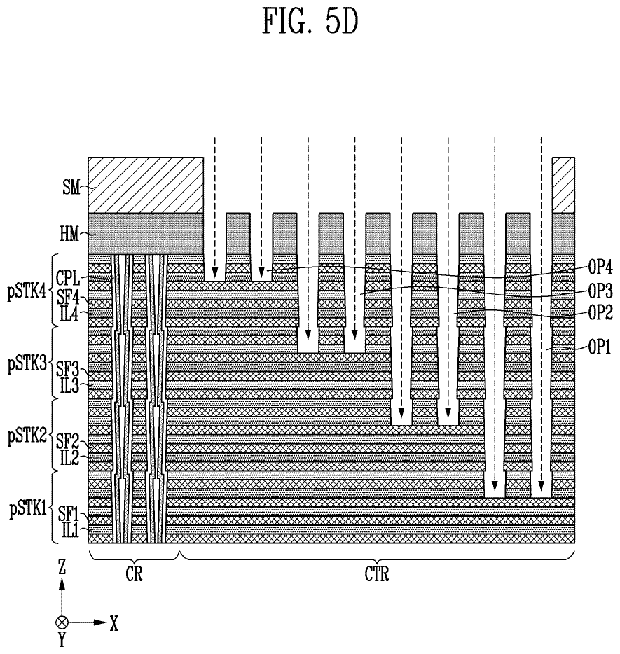

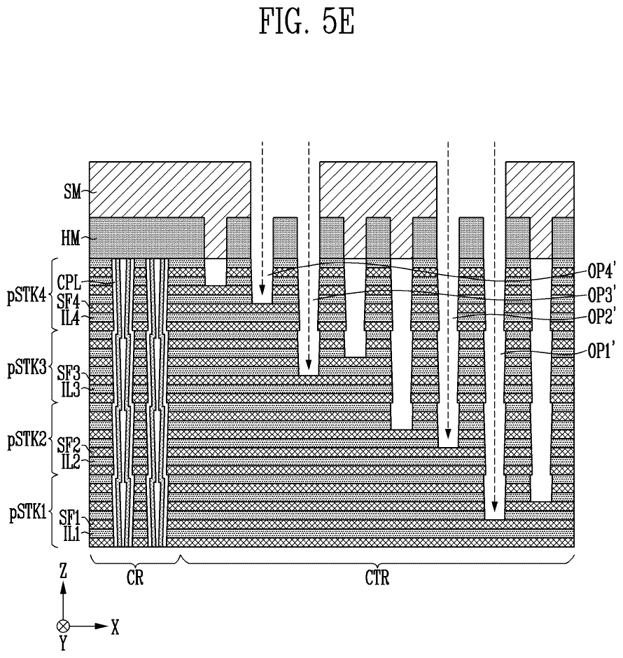

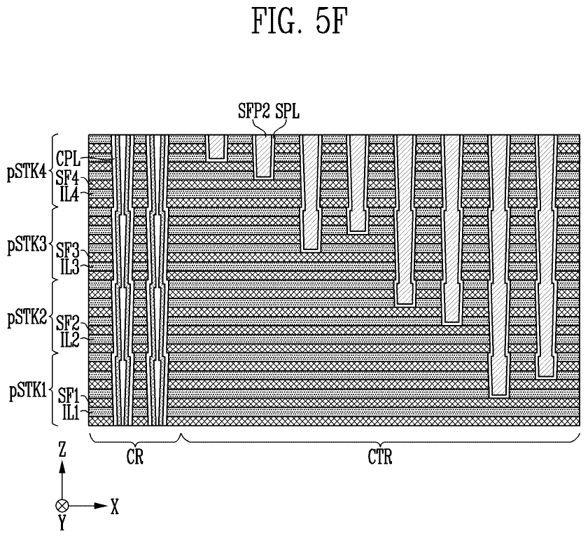

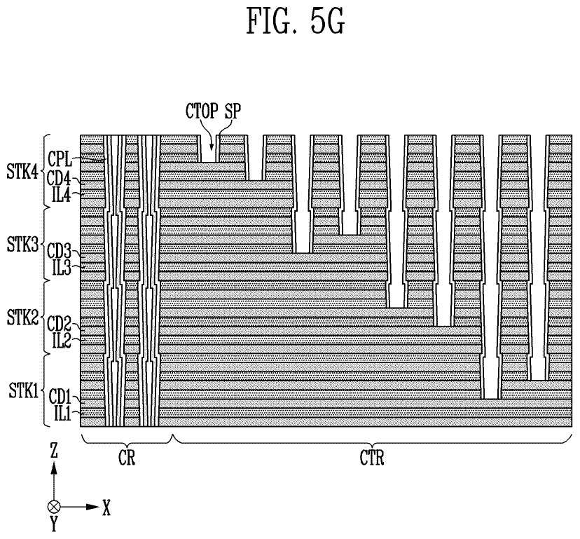

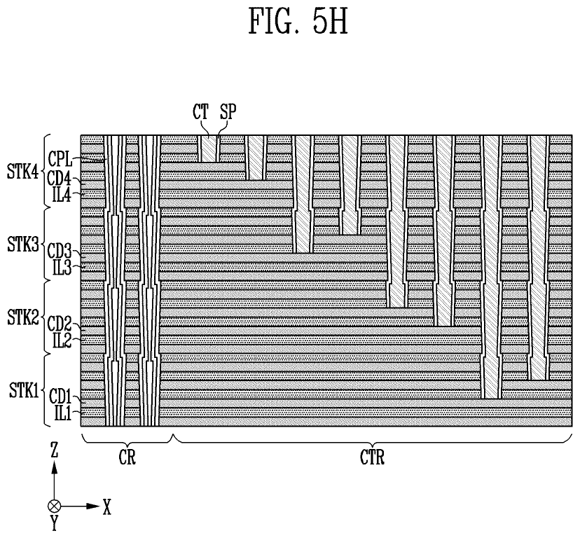

FIGS. 5A to 5H are diagrams for describing a method of manufacturing contacts in four stacks including different sacrificial layers with different etch rates.

FIGS. 5A to 5H are diagrams for describing a method of forming the contacts CT in the contact region CTR when the memory device includes stacks in four layers in a different manner from the method described with reference to FIGS. 4A to 4H. Configurations already described with reference to FIGS. 4A to 4H will be omitted or briefly described in connection with in FIGS. 5A to 5H.

Referring to FIG. 5A, a first preliminary stack pSTK1 may be formed in which the first interlayer insulating layers IL1 and the first sacrificial layers SF1 are stacked alternately with each other. Subsequently, the first cell sacrificial pillars CSP1 may be formed in the cell region CR through the first preliminary stack pSTK1. Subsequently, the second preliminary stack pSTK2 may be formed in which the second interlayer insulating layers IL2 and the second sacrificial layers SF2 are stacked alternately with each other. Subsequently, the second cell sacrificial pillars CSP2 may be formed in the cell region CR through the second preliminary stack pSTK2. The second cell sacrificial pillars CSP2 may overlap the first cell sacrificial pillars CSP1, respectively. In addition, (1-1)th sacrificial pillars SFP1-1 passing through the second preliminary stack pSTK2 may be formed in the contact region CTR.

Subsequently, a third preliminary stack pSTK3 may be formed in which third interlayer insulating layers IL3 and third sacrificial layers SF3 are stacked alternately with each other. Subsequently, third cell sacrificial pillars CSP3 may be formed in the cell region CR through the third preliminary stack pSTK3. The third cell sacrificial pillars CSP3 may overlap the second cell sacrificial pillars CSP2 respectively, and may overlap the first cell sacrificial pillars CSP1 respectively. Furthermore, the (1-2)th sacrificial pillars SFP1-2 passing through the third preliminary stack pSTK3 may be formed in the contact region CTR. Some of (1-2)th sacrificial pillars SFP1-2 may overlap the (1-1)th sacrificial pillars SFP1-1, and the remaining sacrificial pillars (1-2)th might not overlap the (1-1)th sacrificial pillars SFP1-1.

Next, a fourth preliminary stack pSTK4 may be formed in which fourth interlayer insulating layers IL4 and fourth sacrificial layers SF4 are stacked alternately with each other. Subsequently, fourth cell sacrificial pillars CSP4 may be formed in the cell region CR which pass through the fourth preliminary stack pSTK4. The fourth cell sacrificial pillars CSP4 may overlap the third cell sacrificial pillars CSP3, respectively, may overlap the second cell sacrificial pillars CSP2, respectively, and may overlap the first cell sacrificial pillars CSP1, respectively. In addition, (1-3)th sacrificial pillars SFP1-3 passing through the fourth preliminary stack pSTK4 may be formed in the contact region CTR. Some of the (1-3)th sacrificial pillars SFP1-3 may overlap the (1-2)th sacrificial pillars SFP1-2, and the remaining sacrificial pillars SFP1-3 might not overlap the (1-2)th sacrificial pillars SFP1-2.

The first sacrificial layers SF1 may have a first etch rate, the second sacrificial layers SF2 may have a second etch rate, the third sacrificial layer SF3 may have a third etch rate, and the fourth sacrificial layer SF4 may have a fourth etch rate. The first etch rate may be higher than the second etch rate. The second etch rate may be higher than the third etch rate. The third etch rate may be higher than the fourth etch rate. That is, the etch rates of the sacrificial layers may increase toward the lower portion of the stack, and the etch rates of the sacrificial layers may decrease toward the upper portion of the stack. For example, the etch rate of the first to fourth sacrificial layers SF1 to SF4 may be formed as shown in Equation 1 below.

ETCH RATE OF FIRST SACRIFICIAL LAYER SF1>ETCH RATE OF SECOND SACRIFICIAL LAYER SF2>ETCH RATE OF THIRD SACRIFICIAL LAYER SF3>ETCH RATE OF FOURTH SACRIFICIAL LAYER SF4 [Equation 1]

The etch rates of the first to fourth sacrificial layers SF1 to SF4 may be controlled by making various changes in conditions, such as a concentration or type of impurities contained in each sacrificial layer, a ratio of silicon to nitrogen, or the number of thermal treatments, temperature, and duration, as described with reference to FIG. 4A.

Referring to FIG. 5B, the first to fourth cell sacrificial pillars CSP1 to CSP4 may be removed. Spaces from which the first to fourth cell sacrificial pillars CSP1 to CSP4 are removed may be referred to as cell openings. The cell plugs CPL may then be formed in the cell openings. For example, the memory layer ML, the channel layer CH, and the core layer CO may be sequentially formed on the side surfaces of the first to fourth preliminary stacks pSTK1 to pSTK4 which are exposed through the cell openings.

Referring to FIG. 5C, the hard mask HM and the slimming mask SM may be formed on the fourth preliminary stack pSTK4. The hard mask HM may include the mask openings MOP. The (1-1)th to (1-3)th sacrificial pillars SFP1-1 to SFP1-3 as shown in FIG. 5B may be exposed by the mask openings MOP. In addition, a portion of the upper surface of the fourth preliminary stack pSTK4 may be exposed by the mask openings MOP. The slimming mask SM may be in contact with the upper surface of the hard mask HM. The slimming mask SM may include an opening which leaves exposed the mask openings MOP of the hard mask HM.

Subsequently, the (1-1)th sacrificial pillars SFP1-1, the (1-2)th sacrificial pillars SFP1-2, and the (1-3)th sacrificial pillars SFP1-3 may be removed. Through the mask openings MOP, the (1-3)th sacrificial pillars SFP1-3, the (1-2)th sacrificial pillars SFP1-2, and the (1-1)th sacrificial pillars SFP1-1 may be sequentially etched. For example, the (1-3)th sacrificial pillars SFP1-3 may be removed to expose upper surfaces of the (1-2)th sacrificial pillars SFP1-2 and an upper surface of the third preliminary stack pSTK3. Subsequently, the above (1-2)th sacrificial pillars SFP1-2 may be removed.

First preliminary openings POP1 may correspond to spaces from which the (1-1)th sacrificial pillars SFP1-1, the (1-2)th sacrificial pillars SFP1-2, and the (1-3)th sacrificial pillars SFP1-3 are removed. The first preliminary openings POP1 may penetrate through the second to fourth preliminary stacks pSTK2 to pSTK4. The first preliminary openings POP1 may expose the upper surface of the first preliminary stack pSTK1. The second preliminary openings POP2 may correspond to spaces from which the (1-2)th sacrificial pillars SFP1-2 and the (1-3)th sacrificial pillars SFP1-3 are removed. The second preliminary openings POP2 may penetrate through the third and fourth preliminary stacks pSTK3 and pSTK4. The second preliminary openings POP2 may expose the upper surface of the second preliminary stack pSTK2. The third preliminary openings POP3 may correspond to spaces from which the (1-3)th sacrificial pillars SFP1-3 are removed. The third preliminary openings POP3 may penetrate through the fourth preliminary stack pSTK4. The third preliminary openings POP3 may expose the upper surface of the third preliminary stack pSTK3.

Referring to FIG. 5D, a portion of the first to fourth preliminary stacks pSTK1 to pSTK4 which are exposed through the slimming mask SM and the hard mask HM may be etched. Portions of the first preliminary stack pSTK1 which are exposed through the mask opening MOP and the first preliminary opening POP1 may be removed to form the first openings OP1. In addition, portions of the second preliminary stack pSTK2 which are exposed through the mask opening MOP and the second preliminary opening POP2 may be removed to form the second openings OP2. In addition, portions of the third preliminary stack pSTK3 which are exposed through the mask opening MOP and the third preliminary opening POP3 may be removed to form the third openings OP3. In addition, portions of the fourth preliminary stack pSTK4 which are exposed through the mask opening MOP may be removed to form the fourth openings OP4. The first to fourth openings OP1 to OP4 may be spaced apart from each other in the X direction.

The first openings OP1 may extend in the Z direction from any one of the first sacrificial layers SF1. The first openings OP1 may expose the upper surface of any one of the first sacrificial layers SF1. In addition, the second openings OP2 may extend in the Z direction from any one of the second sacrificial layers SF2. The second openings OP2 may expose the upper surface of any one of the second sacrificial layers SF2. In addition, the third openings OP3 may extend in the Z direction from any one of the third sacrificial layers SF3. The third openings OP3 may expose the upper surface of any one of the third sacrificial layers SF3. In addition, the fourth openings OP4 may extend in the Z direction from any one of the fourth sacrificial layers SF4. The fourth openings OP4 may expose the upper surface of any one of the fourth sacrificial layers SF4.

In comparison to FIG. 5C, the first to fourth openings OP1 to OP4 may be etched to the same depth. For example, the first openings OP1 may have a depth corresponding to that of the second first sacrificial layer SF1 from the top of the first sacrificial layers SF1. In addition, the second openings OP2 may have a depth corresponding to that of the second second sacrificial layer SF2 from the top of the second sacrificial layers SF2. In addition, the third openings OP3 may have a depth corresponding to that of the second third sacrificial layer SF3 from the top of the third sacrificial layers SF3. In addition, the fourth openings OP4 may have a depth corresponding to that of the second fourth sacrificial layer SF4 from the top of the fourth sacrificial layers SF4. That is, each of the first to fourth openings OP1 to OP4 may penetrate one of the first to fourth sacrificial layers SF1 to SF4.

The processes of etching the first to fourth preliminary stacks pSTK1 to pSTK4 may be performed simultaneously. For example, when an etch process using an etching gas is performed, each of the first to fourth preliminary stacks pSTK1 to pSTK4 may be etched by the etching gas passing through the mask opening MOP and the first to third preliminary openings POP1 to POP3 to form the first to fourth openings OP1 to OP4. The time taken for the etching gas to reach a target to be etched (e.g., an interlayer insulating layer and a sacrificial layer) may be longer for lower preliminary stacks. For example, the time during which the etching gas reaches the first preliminary stack pSTK1 may be longer than the time during which the etching gas reaches the fourth preliminary stack pSTK4. Therefore, when the first to fourth sacrificial layers SF1 to SF4 have the same etch rate, the degree of etching may be smaller in the lower preliminary stack. However, in the present disclosure, because the etch rates of the sacrificial layers are faster toward the lower part, the preliminary stacks may be etched to the same depth even when the etching gas reaches the target to be etched at different times.

Referring to FIG. 5E, the slimming mask SM may be modified to further cover a portion of the hard mask HM. Some of the first openings OP1, some of the second openings OP2, some of the third openings OP3, and some of the fourth openings OP4 may be left exposed by the modified slimming mask SM. The remaining first openings OP1, the remaining second openings OP2, the remaining third openings OP3, and the remaining fourth openings OP4 may be covered by the slimming mask SM.

Subsequently, a portion of the first preliminary stack pSTK1 exposed through the first opening OP1 may be etched to form an extended first opening OP1′. In addition, a portion of the second preliminary stack pSTK2 exposed through the second opening OP2 may be etched to form an extended second opening OP2′. In addition, a portion of the third preliminary stack pSTK3 exposed through the third opening OP3 may be etched to form an extended third opening OP3′. In addition, a portion of the fourth preliminary stack pSTK4 exposed through the fourth opening OP4 may be etched to form an extended fourth opening OP4′.

The extended first to fourth opening portions OP1′ to OP4′ may be formed to a greater depth than the first to fourth opening portion OP1 to OP4 by a length corresponding to a single sacrificial layer and a single interlayer insulating layer. For example, the extended first to fourth openings OP1′ to OP4′ may have a depth corresponding to that of the third sacrificial layer from the top among the first to fourth sacrificial layers SF1 to SF4. That is, each of the extended first to fourth openings OP1′ to OP4′ may penetrate the two layers of each of the first to fourth sacrificial layers SF1 to SF4.

As described for FIG. 5D, the processes of etching the first to fourth preliminary stacks pSTK1 to pSTK4 may be performed simultaneously. For example, when an etch process using an etching gas is performed, the time during which the etching gas reaches the first preliminary stack pSTK1 may be longer than the time during which the etching gas reaches the second to fourth preliminary stacks pSTK2 to pSTK4. In the present disclosure, because the etch rates of the sacrificial layers are faster toward the lower part, the preliminary stacks may be etched by the same amount or depth even when the arrival time of the etching gas is different from each other.

Referring to FIG. 5F, the slimming mask SM and the hard mask HM may be removed. Subsequently, the spacer layers SPL may be formed on the inner surfaces of the first to fourth openings OP1 to OP4 and the extended first to fourth opening OP1′ to OP4′. Subsequently, the second sacrificial pillars SFP2 may be formed in the first to fourth openings OP1 to OP4 and the extended first to fourth opening OP1′ to OP4′.

Referring to FIG. 5G, the first to fourth sacrificial layers SF1 to SF4 may be replaced with the first to fourth conductive layers CD1 to CD4, respectively. The first conductive layers CD1 and the first interlayer insulating layers IL1 may form the first stack STK1. The second conductive layers CD2 and the second interlayer insulating layers IL2 may form the second stack STK2. The third conductive layers CD3 and the third interlayer insulating layers IL3 may form a third stack STK3. The fourth conductive layers CD4 and the fourth interlayer insulating layers IL4 may form a fourth stack STK4.

Subsequently, the first to fourth openings OP1 to OP4 and the second sacrificial pillars SFP2 in the extended first to fourth opening OP1′ to OP4′ may be removed. The second sacrificial pillars SFP2 may be removed to form the contact openings CTOP. Subsequently, the lower surfaces of the spacer layers SPL may be removed through the contact openings CTOP to form the spacers SP.

Referring to FIG. 5H, the contacts CT may be formed to fill the contact openings CTOP, respectively. The contacts CT may be in contact with the first to fourth conductive layers CD1 to CD4, respectively. The contacts CT may be electrically coupled to the first to fourth conductive layers CD1 to CD4, respectively. The contacts CT may each be surrounded by the spacers SP. Therefore, each of the contacts CT may be electrically coupled to one conductive layer and electrically insulated from the other conductive layers.

According to the present disclosure, as described with reference to FIGS. 5D and 5E, by forming the first to fourth sacrificial layers SF1 to SF4 with different etch rates, openings (e.g., OP1 to OP4) for contacts (CT) may be formed. Therefore, by controlling the etch rates of the first to fourth sacrificial layers SF1 to SF4, the quality of the contacts CT may be improved and the manufacturing process of the contacts CT may be complemented.

FIGS. 4A to 4H show embodiments in which a memory device includes two stacks (STK1 and STK2), and FIGS. 5A to 5H show embodiments in which a memory device includes four stacks (STK1 to STK4). However, the present disclosure is not limited thereto. For example, in some embodiments, a memory device may include three stacks or five or more stacks. These embodiments may also be included in the scope of the present disclosure as the depth of the contact opening is adjusted by controlling the relative etch rates of sacrificial layers included in different stacks.

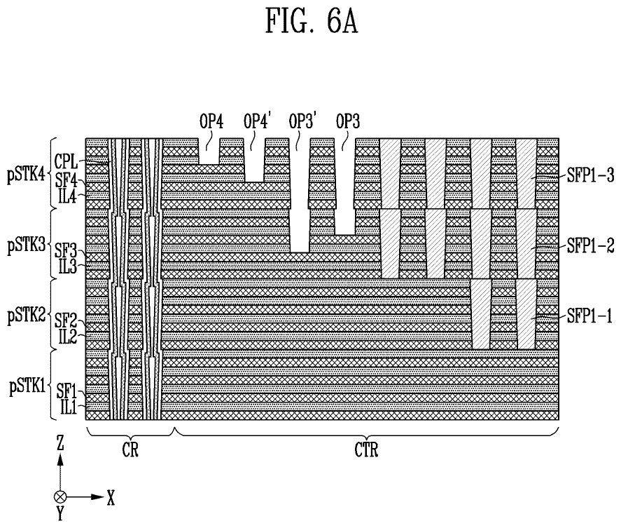

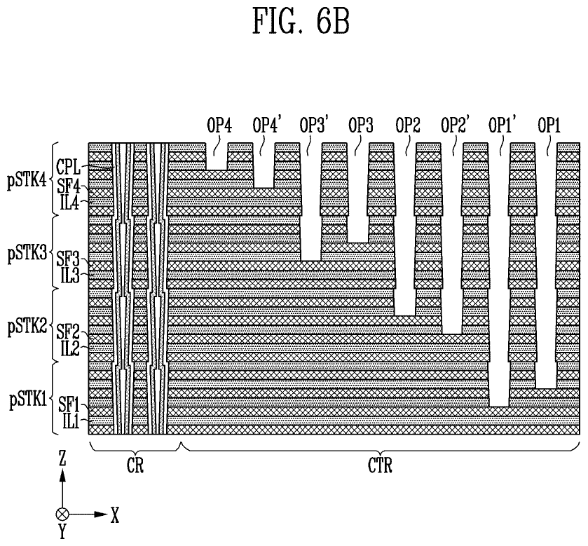

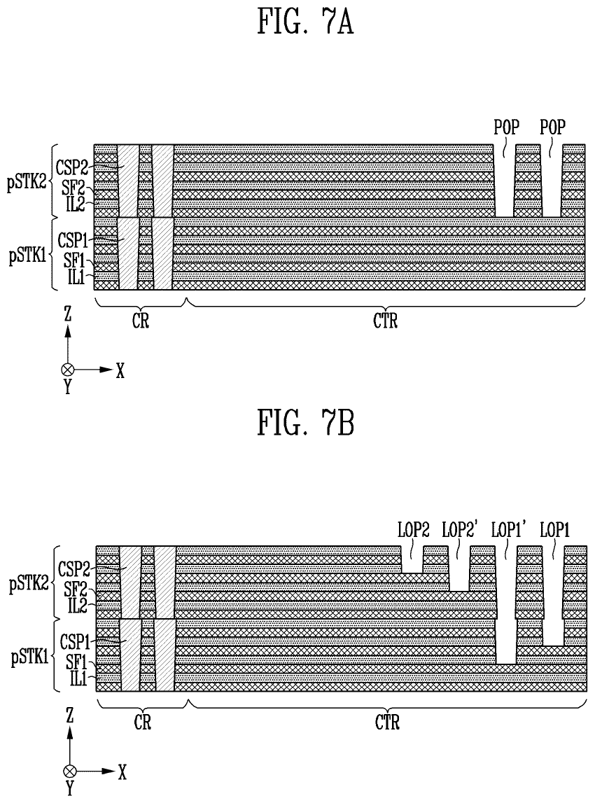

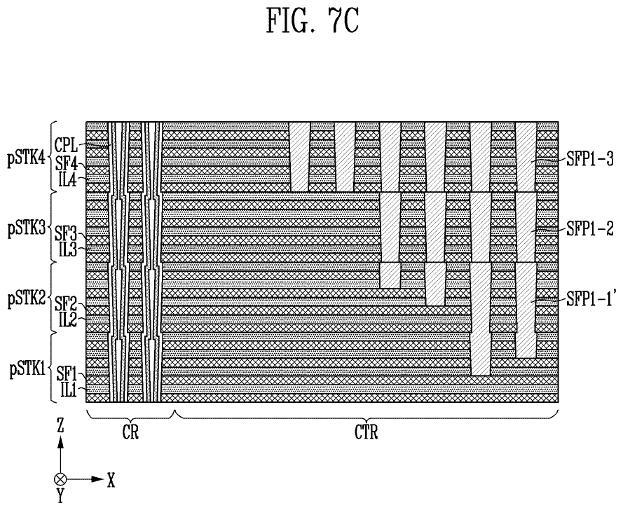

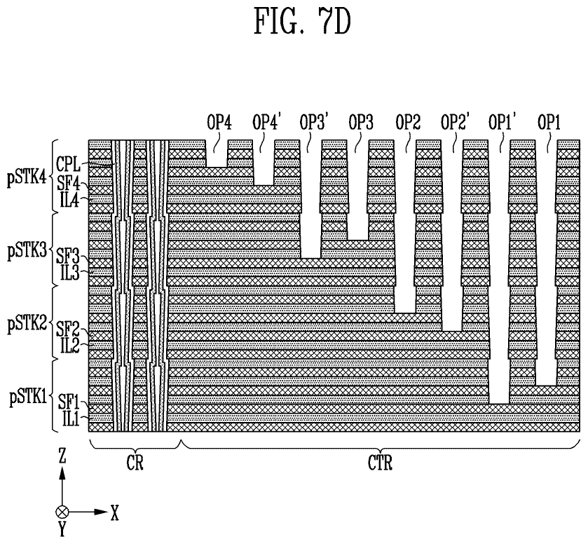

In addition, though FIGS. 4A to 4H and FIGS. 5A to 5H describe embodiments in which etch rates of the sacrificial layers increase toward the lower part, the present disclosure is not limited thereto. For example, when a memory device includes four stacks, the upper two stacks may include sacrificial layers with different etch rates, and the lower two stacks may include sacrificial layers with different etch rates. The corresponding embodiment is described below with reference to FIGS. 6A and 6B and FIGS. 7A to 7D.

FIGS. 6A and 6B are diagrams for describing a method of manufacturing contacts in stacks according to another embodiment of the present disclosure. With regard to FIG. 6A and FIG. 6B, only the differences from FIGS. 5A to 5H are described, and the descriptions made with reference to FIGS. 5A and 5H may be referenced with respect for configurations which are not described herein.

The first sacrificial layers SF1 may have a first etch rate, and the second sacrificial layers SF2 may have a second etch rate. In addition, the third sacrificial layers SF3 may have the first etch rate, and the fourth sacrificial layer SF4 may have the second etch rate. The second etch rate may be lower than the first etch rate. That is, the first sacrificial layers SF1 and the third sacrificial layers SF3 may have a fast etch rate, and the second sacrificial layer SF2 and the fourth sacrificial layer SF4 may have a slow etch rate. For example, the etch rates of the first to fourth sacrificial layers SF1 to SF4 may be defined as shown below in Equation 2.

ETCH RATE OF FIRST SACRIFICIAL LAYER (SF1)=ETCH RATE OF THIRD SACRIFICIAL LAYER (SF3)>ETCH RATE OF SECOND SACRIFICIAL LAYER (SF2)=ETCH RATE OF FOURTH SACRIFICIAL LAYER (SF4) [Equation 2]

In another embodiment, the first sacrificial layers SF1 and the third sacrificial layers SF3 may have different etch rates, and the second sacrificial layer SF2 and the fourth sacrificial layer SF4 may have different etch rates. In other words, embodiments of the present disclosure may include the first sacrificial layers SF1 having a faster etch rate than the second sacrificial layer SF2 and the third sacrificial layers SF3 having a faster etch rate than the fourth sacrificial layer SF4.

Referring to FIG. 6A, openings may be formed in the third and fourth preliminary stacks pSTK3 and pSTK4. When the (1-1)th sacrificial pillars SFP1-1, the (1-2)th sacrificial pillars SFP1-2, and the (1-3)th sacrificial pillars SFP1-3 remain, the fourth opening OP4 and the extended fourth opening OP4′ coupled to the fourth sacrificial layers SF4, and the third opening OP3 and the extended third opening OP3′ coupled to the third sacrificial layer SF3 may be formed.

Referring to FIG. 6B, the (1-1)th sacrificial pillars SFP1-1, the (1-2)th sacrificial pillars SFP1-2, and the (1-3)th sacrificial pillars SFP1-3 may be removed, and the second opening OP2 and the extended second opening OP2′ coupled to the second sacrificial layers SF2 and the first opening OP1 and the extended first opening OP1′ coupled to the first sacrificial layer SF1 may be formed. The processes described for FIGS. 5F to 5H may then be performed.

That is, as described above with reference to FIGS. 6A and 6B, the openings (e.g., OP3, OP3′, OP4, and OP4′) corresponding to the upper two stacks may be formed first, and then openings (e.g., OP1, OP1′, OP2, and OP2′) corresponding to the lower two stacks may be formed.

FIGS. 7A to 7D are diagrams for describing a method of manufacturing contacts in stacks according to another embodiment of the present disclosure. In FIG. 7A to FIG. 7D, only the differences from FIGS. 5A to 5H and FIG. 6A and FIG. 6B are described. In addition, FIG. 5A and FIG. 5H, and FIGS. 6A and 6B may be referenced for configurations which are not described.

As described with reference to FIGS. 6A and 6B, the first sacrificial layers SF1 may have a faster etch rate than the second sacrificial layers SF2. In FIGS. 7A to 7D, openings may be formed in the first and second preliminary stacks pSTK1 and pSTK2 before the third preliminary stack pSTK3 is formed.

Referring to FIG. 7A, the preliminary openings POP penetrating through the second preliminary stack pSTK2 may be formed. The preliminary openings POP may expose a portion of the upper surface of the first preliminary stack pSTK1.

Referring to FIG. 7B, a first lower opening LOP1 an extended first lower opening LOP1′ each coupled to the first sacrificial layers SF1 and may be formed. In addition, a second lower opening LOP2 and an extended second lower opening LOP2′ each coupled to the second sacrificial layers SF2 may be formed. That is, etch processes may be performed so that the openings may be coupled to the first and second sacrificial layers SF1 and SF2 before the third preliminary stack pSTK3 is formed.

Referring to FIG. 7C, (1-1)th sacrificial pillars SFP1-1′ may be formed in the first lower opening LOP1, the extended first lower opening LOP1′, the second lower opening LOP2, and the extended second lower opening LOP2′.

Subsequently, a third preliminary stack pSTK3 and (1-2)th sacrificial pillars SFP1-2 may be formed. The fourth preliminary stack pSTK4 and (1-3)th sacrificial pillars SFP1-3 may then be formed. Subsequently, cell sacrificial pillars (e.g., CSP1 and CSP2) may be removed and cell plugs (CPL) formed.

Referring to FIG. 7D, the fourth opening OP4 and the fourth extended opening OP4′ coupled to the fourth sacrificial layers SF4, and the third opening OP3 and a third extended opening OP3′ coupled to the third sacrificial layer SF3 may be formed.

Subsequently, the (1-1)th sacrificial pillars SFP1-1′, the (1-2)th sacrificial pillars SFP1-2, and the (1-3)th sacrificial pillars SFP1-3 may be removed to form the first opening OP1, the extended first opening OP1′, the second opening OP2, and the extended second opening OP2′.

In other words, referring to FIGS. 7A to 7D, the openings (e.g., OP1, OP1′, OP2, and OP2′) corresponding to the lower two stacks may be formed first, and then openings (e.g., OP3, OP3′, OP4, and OP4′) corresponding to upper two stacks may also be formed.

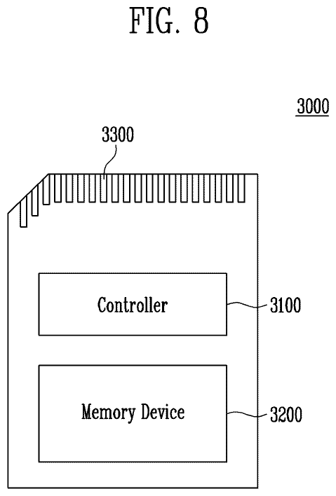

FIG. 8 is a diagram illustrating a memory card system 3000 to which a memory device according to an embodiment of the present disclosure is applied.

Referring to FIG. 8, the memory card system 3000 may include a controller 3100, a memory device 3200, and a connector 3300.

The controller 3100 may be coupled to the memory device 3200. The controller 3100 may be configured to access the memory device 3200. For example, the controller 3100 may control a program operation, a read operation or an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components such as Random-Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

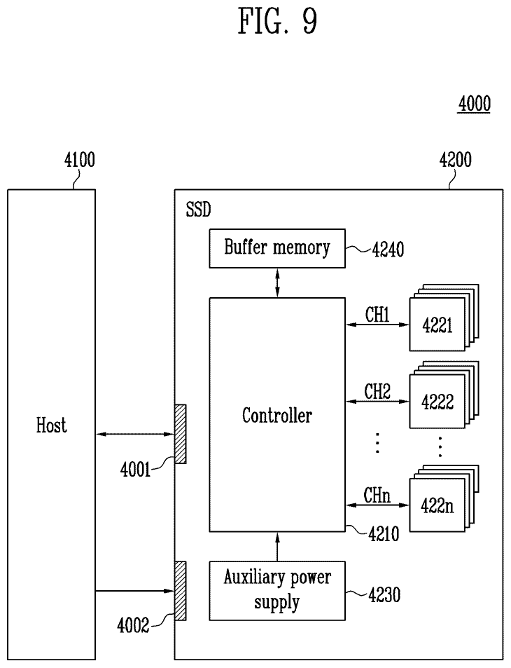

FIG. 9 is a diagram illustrating a solid-state drive (SSD) system 4000 to which a memory device according to an embodiment of the present disclosure is applied.

Referring to FIG. 9, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive power input from the host 4100 and charge the power. When the supply of power from the host 4100 is not smooth, the auxiliary power supply 4230 may provide power of the SSD 4200. For example, the auxiliary power supply 4230 may be inside or outside the SSD 4200. For example, the auxiliary power supply 4230 may be on a main board and provide auxiliary power to the SSD 4200.

The buffer memory 4240 may serve as buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to an embodiment of the present disclosure, by controlling etch rates of sacrificial layers stacked alternately with interlayer insulating layers, the quality of contacts may be improved and a manufacturing processes of the contacts may be complemented.

It will be apparent to those skilled in the art that various modifications can be made to the above-described embodiments of the present teachings without departing from the spirit or scope of the disclosure. Thus, it is intended that the present teachings cover all such modifications provided they come within the scope of the appended claims and their equivalents.

What is claimed is:

1. A method of manufacturing a memory device, the method comprising:
forming a lower stack including first interlayer insulating layers and first sacrificial layers alternately stacked with each other in a first direction;
forming an upper stack over the lower stack in the first direction, wherein the upper stack includes second interlayer insulating layers and second sacrificial layers alternately stacked with each other in the first direction, the second sacrificial layers having a lower etch rate than the first sacrificial layers;
forming a preliminary opening penetrating through the upper stack and exposing an upper surface of the lower stack; and
forming a first opening extending in the first direction from one of the first sacrificial layers and a second opening extending in the first direction from one of the second sacrificial layers by simultaneously etching a portion of the lower stack exposed through the preliminary opening and a portion of the upper stack spaced apart from the preliminary opening.

2. The method of claim 1, wherein in forming the lower stack and forming the upper stack,
the second sacrificial layers include a higher concentration of an impurity than the first sacrificial layers.

3. The method of claim 2, wherein the impurity comprises carbon.

4. The method of claim 1, wherein in forming the lower stack and forming the upper stack,
the first sacrificial layers and the second sacrificial layers include nitrogen (N) and silicon (Si), respectively, and
a ratio of Si included in the second sacrificial layers is higher than a ratio of Si included in the first sacrificial layers.

5. The method of claim 1, further comprising, after the forming of the upper stack, forming a first sacrificial pillar passing through the upper stack.

6. The method of claim 5, wherein forming the preliminary opening includes removing the first sacrificial pillar.

7. The method of claim 1, wherein in forming the first opening and the second opening,
a height of a region of the first opening, except for the preliminary opening, corresponds to a height of the second opening.

8. The method of claim 1, further comprising, after the forming the first opening and the second opening,
forming a third opening extending by a first length more than the first opening and forming a fourth opening extending by the first length more than the second opening by simultaneously etching a portion of the lower stack exposed through the first opening and a portion of the upper stack exposed through the second opening.

9. The method of claim 1, further comprising after forming the first opening and forming the second opening:
forming spacer layers on an inner surface of the first opening and an inner surface of the second opening;
forming second sacrificial pillars surrounded by the spacer layers, respectively;
replacing the first sacrificial layers and the second sacrificial layers with conductive layers;
removing the second sacrificial pillars;
forming spacers exposing portions of the conductive layers by etching respective lower ends of the spacer layers; and
forming contacts contacting the conductive layers, respectively, and surrounded by the spacers, respectively.

10. The method of claim 1, further comprising, after forming the lower stack, forming first cell sacrificial pillars penetrating the lower stack.

11. The method of claim 10, further comprising, after forming the top stack:
forming second cell sacrificial pillars penetrating the upper stack and overlapping the first cell sacrificial pillars, respectively;
forming cell openings penetrating each of the lower stack and the upper stack by removing the first cell sacrificial pillars and the second cell sacrificial pillars; and
forming cell plugs in the cell openings.

12. A method of manufacturing a memory device, comprising:
forming a first stack including first interlayer insulating layers and first sacrificial layers alternately stacked with each other, the first sacrificial layers having a first etch rate;
forming a second stack over the first stack, wherein the second stack includes second interlayer insulating layers and second sacrificial layers alternately stacked with each other, the second sacrificial layers having a second etch rate lower than the first etch rate;
forming first sacrificial pillars penetrating through the second stack;
forming preliminary openings by removing the first sacrificial pillars;
forming first openings penetrating a first number of the first sacrificial layers, respectively, by etching a portion of the first stack through the preliminary openings;
forming second openings penetrating the first number of the second sacrificial layers, respectively, by etching a portion of the second stack spaced apart from the preliminary openings; and
forming contacts in the first openings and the second openings.

13. The method of claim 12, further comprising, after forming the first sacrificial pillars:
forming a third stack over the second stack, wherein the third stack includes third interlayer insulating layers and third sacrificial layers alternately stacked with each other, the third sacrificial layers having a third etch rate; and
forming second sacrificial pillars passing through the third stack,
wherein the third etch rate is lower than the first etch rate and the second etch rate; and
wherein one or more of the second sacrificial pillars overlap the first sacrificial pillars, respectively.

14. The method of claim 13, wherein forming the preliminary openings by removing the first sacrificial pillars includes:
removing the second sacrificial pillars to expose the first sacrificial pillars and portions of an upper surface of the second stack; and
removing exposed first sacrificial pillars;
wherein the preliminary openings comprise spaces left after the first sacrificial pillars and the second sacrificial pillars are removed.

15. The method of claim 14, wherein in forming the second openings,
the second openings are formed by etching a portion of the second stack through the preliminary openings.

16. The method of claim 13, further comprising,
forming third openings penetrating the first number of the third sacrificial layers by etching a portion of the third stack spaced apart from the preliminary openings.

17. The method of claim 12, wherein forming the first openings and forming the second openings are performed concurrently.

18. The method of claim 12, further comprising, after forming the first openings and forming the second openings,
forming extended first openings penetrating a second number of the first sacrificial layers and forming extended second openings penetrating the second number of the second sacrificial layers, wherein the second number is greater than the first number, by simultaneously etching portions of the first stack exposed through the first openings and portions of the second stack exposed through the second openings.
